(19) United States
(12) Patent Application Publication
(10) Pub. No.: US 2013/0247967 A1
(43) Pub. Date: Sep. 26, 2013

(54) GASEOUS OZONE (O3) TREATMENT FOR SOLAR CELL FABRICATION

(71) Applicant: Scott Harrington, Oakland, CA (US)

(72) Inventor: Scott Harrington, Oakland, CA (US)

(21) Appl. No.: 13/429,134

(22) Filed: Mar. 23, 2012

(51) Int. Cl. H01L 31/0236; H01L 21/306; H01L 31/18

(52) U.S. Cl. 136/256; 438/71; 156/345.11; 156/345.22; 257/E31.13

(57) ABSTRACT

Methods of fabricating solar cells and apparatuses for fabricating solar cells are described. In an example, a method of fabricating a solar cell includes treating a light-receiving surface of a substrate with a gaseous ozone (O₃) process. Subsequently, the light-receiving surface of the substrate is texturized.

### TECHNICAL FIELD

Embodiments of the present invention are in the field of renewable energy and, in particular, methods of fabricating solar cells and apparatuses for fabricating solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Embodiments of the present invention allow for increased solar cell efficiency and increased solar cell manufacture efficiency by providing novel processes and apparatuses for fabricating solar cell structures.

### BRIEF DESCRIPTION OF THE DRAWINGS

FIG. 1 illustrates two texturization processes: (a) a conventional process and (b) a process including an initial ozone gas treatment, in accordance with an embodiment of the present invention.

FIG. 2A illustrates a cross-sectional view of an operation including treating a light-receiving surface of a substrate with a gaseous ozone (O₃) process in a method of fabrication a solar cell, in accordance with an embodiment of the present invention.

FIG. 2B illustrates a cross-sectional view of an operation including treating the light-receiving surface of the substrate of FIG. 2A with a pre-texturizing wet clean process in a method of fabrication a solar cell, in accordance with an embodiment of the present invention.

FIG. 2C illustrates a cross-sectional view of an operation including texturizing the light-receiving surface of the substrate of either FIG. 2A or 2B in a method of fabrication a solar cell, in accordance with an embodiment of the present invention.

FIG. 2D illustrates a cross-sectional view of an operation including forming back contacts for a back-contact solar cell using the substrate of FIG. 2C, in accordance with an embodiment of the present invention.

FIG. 2E illustrates a cross-sectional view of an operation including forming back contacts for another back-contact solar cell, in accordance with an embodiment of the present invention.

FIG. 3 is a plot showing Jsc (short circuit current) improvement (mA/cm²) as a function of the use or non-use of a gaseous ozone pre-treatment operation, in accordance with an embodiment of the present invention.

FIG. 4 illustrates a block diagram of an example of an apparatus for fabricating solar cells, in accordance with an embodiment of the present invention.

FIG. 5 illustrates a block diagram of an example of a computer system configured for performing a method of fabricating a solar cell, in accordance with an embodiment of the present invention.

### DETAILED DESCRIPTION

Methods of fabricating solar cells and apparatuses for fabricating solar cells are described herein. In the following description, numerous specific details are set forth, such as specific process flow operations, in order to provide a thorough understanding of embodiments of the present invention. It will be apparent to one skilled in the art that embodiments of the present invention may be practiced without these specific details. In other instances, well-known fabrication techniques, such as metal contact formation techniques, are not described in detail in order to not unnecessarily obscure embodiments of the present invention. Furthermore, it is to be understood that the various embodiments shown in the figures are illustrative representations and are not necessarily drawn to scale.

Disclosed herein are methods of fabricating a solar cell. In one embodiment, a method of fabricating a solar cell includes treating a light-receiving surface of a substrate with a gaseous ozone (O₃) process. Subsequently, the light-receiving surface of the substrate is texturized. In another embodiment, a method of fabricating a solar cell includes treating a light-receiving surface of a substrate with a gaseous ozone (O₃) process. Subsequently, the light-receiving surface is treated using an aqueous potassium hydroxide (KOH) solution having a weight percent approximately in the range of 20-45, at a temperature approximately in the range of 60-85 degrees Celsius, for a duration approximately in the range of 60-120 seconds. Subsequently, the light-receiving surface of the substrate and at least a portion of a surface of the substrate opposite the light-receiving surface are texturized. The texturizing includes treating the substrate with an aqueous alkaline process. Subsequently, a back-contact solar cell is formed from the substrate by forming contacts on the surface of the substrate opposite the light-receiving surface.

Also disclosed herein are apparatuses for fabricating solar cells. In one embodiment, an apparatus for forming a solar cell includes a first chamber configured for coupling a gaseous ozone (O₃) source and for flowing a stream of ozone gas across a substrate in the first chamber. A second chamber is configured for treating a substrate with an aqueous alkaline texturizing process.

Many silicon solar cell designs utilize random alkaline texturing of the front surface to decrease reflectance and increase the efficiency of the solar cell. Such texturing solutions typically include an alkaline etchant, such as sodium hydroxide (NaOH), potassium hydroxide (KOH) or tetramethylammonium hydroxide (TMAH), and a surfactant, such as iso-propyl alcohol (IPA) or similar alcohol. During texturing of a surface of a substrate or layer for a solar cell with alkaline chemistries, organic matter disposed on the substrate or layer may act as a micro-mask to block the texturing at least in some regions. Such blocking of the texturing may negatively impact the surface texturing uniformity and quality. Nonetheless, organic matter may be ubiquitous in photovoltaic (PV) manufacturing. Accordingly, one or more embodiments described herein are directed to a method to clean wafers, substrates or layers of organic residues prior to performing a texturing process. Such cleaning may improve texturing quality dramatically.

In accordance with an embodiment of the present invention, methods described herein may be used to improve texturing quality and homogeneity for silicon solar cells. As a contrasting example, conventional methods for cleaning organics have included the use of chemical cleaning baths that utilize oxidizing chemistries such as sulfuric acid and hydrogen peroxide (e.g., a piranha clean), ammonium hydroxide and hydrogen peroxide (e.g., SC1), ozone and high purity water as a wet etch or cleans application. Such oxidizing chemistries have increased the texturing equipment cost as well as the use of consumables, resulting in higher chemical costs and disposal costs.

Using ozone in combination with high purity water may reduce the added chemical costs compared to the other chemical cleaning baths. However, this approach may suffer from a high rate of decay of ozone in aqueous solutions, complexity and cost of needed pumps, ozone contactors, and expensive bath materials resistant to ozone dissolved in water. Instead, in accordance with an embodiment of the present invention, immersing silicon wafers directly in an ozone gas reduces the equipment complexity and cost compared to conventional chemical methods for cleaning organics from the surfaces of wafers. Also, high purity water or other such consumables may not be required aside from a small quantity of oxygen gas used as a source of ozone. In one embodiment, since ozone typically decays much more slowly in the gas phase, a gas phase treatment requires less actual ozone usage as compared to a treatment using ozone mixed with high purity water. An ozone gas process may also be significantly simpler, easier and less expensive to retrofit to existing equipment.

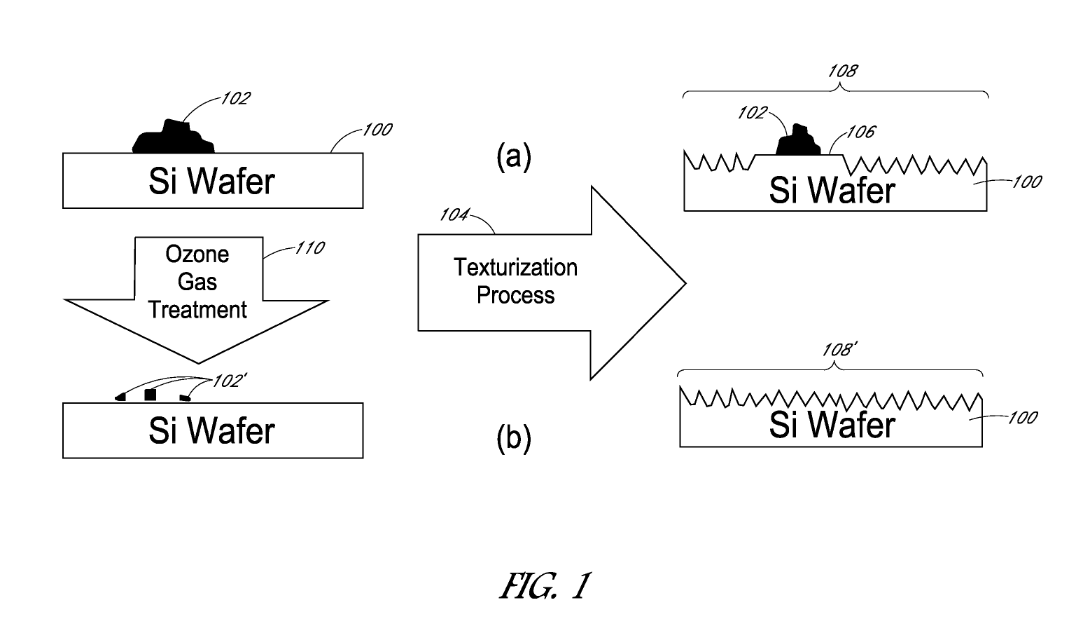

To illustrate the utility of certain aspects of embodiments of the present invention, FIG. 1 illustrates two texturization processes: (a) a conventional process and (b) a process including an initial ozone gas treatment, in accordance with an embodiment of the present invention. Referring to FIG. 1, a substrate 100 (such as a silicon wafer) for fabricating a solar cell is incoming to a texturization process with impurities 102, such as an organic residue. Following pathway (a), when the structure 100/102 is exposed directly to a texturization process 104 (such as an alkaline process described below), the organic residue 102 may act as a micro-mask to inhibit texturing in some areas (e.g., flat portion 106) leading to a poor quality texture 108 over the wafer surface. The organic residue 102 is shown as smaller after the texturization process 104 since it may be reduced in the process 104. However, a sizeable enough portion may remain to interfere with the texturization, as is shown in pathway (a).

By contrast, in an embodiment, following pathway (b), the substrate 100 (such as a silicon wafer) for fabricating a solar cell is incoming to a texturization process with impurities 102, such as an organic residue. Prior to process 104, the substrate 100 is exposed to an ozone gas treatment 110. The ozone gas treatment 110 can either completely or partially remove the organic residue 102, or can break down organic residue 102 to smaller fragments 102′, as depicted in FIG. 1. By completely removing the organic residue 102, in one embodiment, the organic residue can no longer act as a micro-mask during texturing 104. By partially removing the organic residue 102 or breaking down organic residue 102 to smaller fragments 102′, in one embodiment, the organic reside can be removed during the texturizing process and/or is small enough to not substantially impact the resulting texturizing pattern. Thus, by applying an initial gaseous ozone process, flat spots that otherwise negatively impact texturing quality are either eliminated or at least mitigated to provide a substantially more homogeneous textured surface 108′. In a specific embodiment, ozone gas volatilizes and attacks organic compounds, which results in a clean wafer surface going into a texturing bath, resulting in improved texturing. Also, in an embodiment, extended bath life of a texturizing solution may be realized since organic residue contamination is eliminated or mitigated. In an embodiment, the extent of any pre-texturizing clean may be reduced or even supplanted by first using a gaseous ozone treatment.

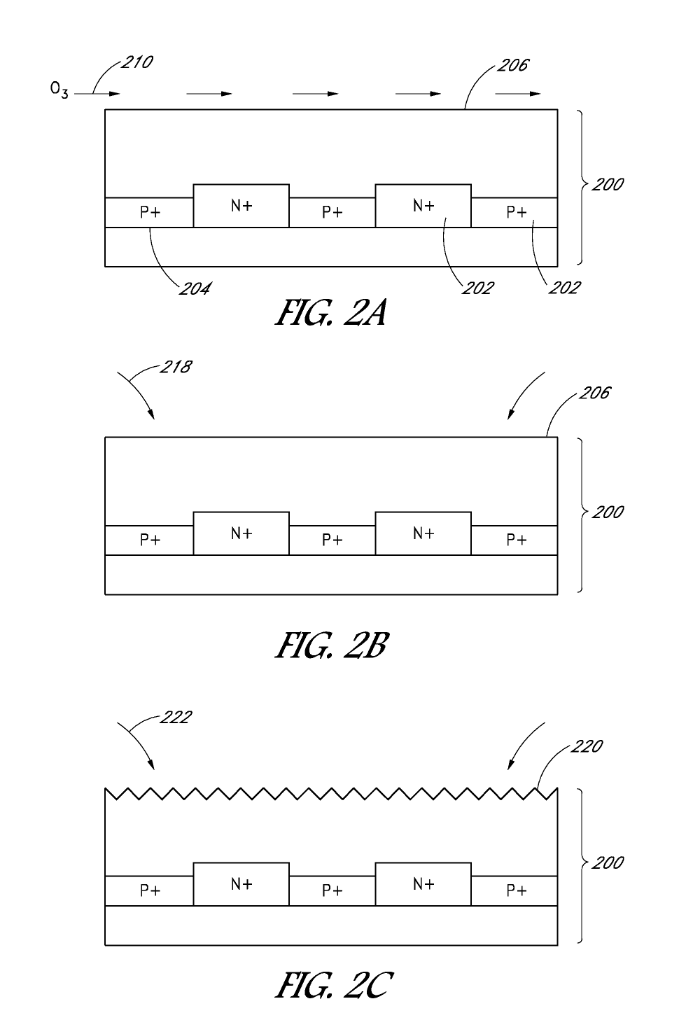

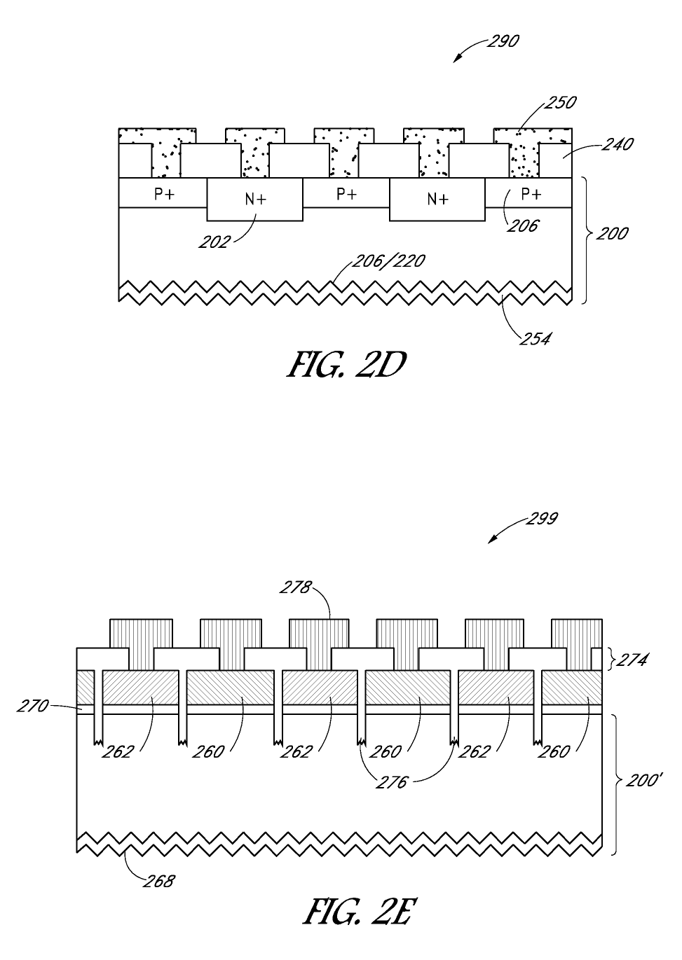

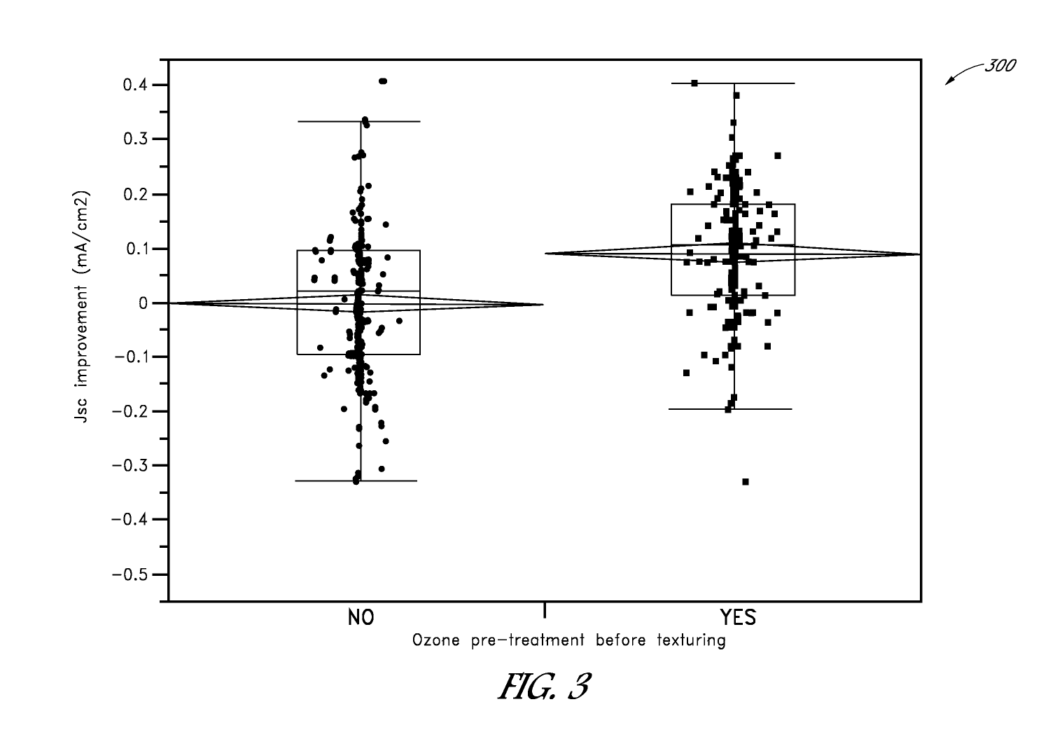

In an aspect, a gaseous ozone process may be included in a processing scheme for fabricating a solar cell. For example, FIGS. 2A-2E illustrate various operations in the fabrication of a solar cell, in accordance with one or more embodiments of the present invention.

Referring to FIG. 2A, a substrate 200 is provided in the fabrication of a back-contact solar cell. As an example of features that may be included, substrate 200 includes a plurality of active regions 202 on a back surface 204, opposing a light-receiving surface 206. The plurality of active regions 202 includes alternating N+ and P+ regions. In one embodiment, substrate 200 is composed of crystalline N-type silicon, the N+ regions include phosphorous dopant impurity atoms and the P+ regions include boron dopant impurity atoms. An insulating or other protecting layer 208 may be included on the back surface 204 during a texturing process, as depicted in FIG. 2A.

Referring again to FIG. 2A, in an embodiment, a method of fabricating a solar cell includes treating the light-receiving surface 206 of the substrate 200 with a gaseous ozone (O₃) process 210. In one such embodiment, the gaseous ozone process 210 includes flowing a stream of ozone gas partially or entirely across the light-receiving surface 206 of the substrate 200.

In an embodiment, substrate 200 is exposed to ozone gas prior to application of a texturing bath. The duration of exposure may be sufficiently long to provide effective treatment, while sufficiently short to avoid diminishing returns of the treatment as compared to cost and ozone handling. The exposure to ozone is, in one embodiment, for a duration between approximately 1 and 5 minutes. The ozone may oxidize a top portion of substrate 200 while also breaking down, or eliminating, organic residue on the substrate surface, e.g., surface 206. In a specific embodiment, flowing the stream of ozone gas includes maintaining the substrate 200 at a temperature approximately in the range of 15-40 degrees Celsius and flowing for a duration approximately in the range of 1-3 minutes.

In an embodiment, treating the light-receiving surface 206 of the substrate 200 with the gaseous ozone process 210 includes removing at least a portion of an organic residue disposed on the light-receiving surface of the substrate. For example, organics may be removed that are incoming residue from mask etch strip, e.g., from a PCB type mask, or from ink used in a screen print mask. The organic matter may become volatile and leave the substrate surface or be broken down to shorter carbon chain molecules that are easier to undercut and remove in alkaline etching baths. In a specific such embodiment, removing the portion of the organic residue includes oxidizing the organic residue according to equation (1):

O₃ (g)+organic residue (s)→O₂ (g)+oxidized organic species (g) (1)

Referring to FIG. 2B, in an embodiment, prior to performing a texturing process, the light-receiving surface 206 of the substrate 202 is treated with a pre-texturizing wet clean process 218. In one such embodiment, the pre-texturizing wet clean process 218 includes treatment with an aqueous hydroxide solution, such as but not limited to an aqueous potassium hydroxide (KOH) solution, an aqueous sodium hydroxide (NaOH) solution, or an aqueous tetramethylammonium hydroxide (TMAH) solution. In a specific such embodiment, the pre-texturizing wet clean process 218 includes treatment with an aqueous potassium hydroxide (KOH) solution having a weight percent approximately in the range of 20-45, at a temperature approximately in the range of 60-85 degrees Celsius, for a duration approximately in the range of 60-120 seconds. In an embodiment, the treatment with an aqueous hydroxide solution is followed by a rinse, e.g., with deionized (DI) water.

Thus, in an embodiment, a texturizing process (described below) may be combined with an alkaline etching bath cleans process prior to using a texturing bath. In this way, the ozone gas treatment described in association with FIG. 2A may be used to oxidize a silicon wafer. Following, the preliminary alkaline etching bath treatment may be used to undercut any contaminants on the surface to provide for a clean and uniform silicon surface prior to entering the texturing bath.

Referring to FIG. 2C, the method also includes texturizing the light-receiving surface 206 of the substrate 200, e.g., to form a textured surface 220. In an embodiment, light-receiving surface 206 is textured to mitigate undesirable reflection during solar radiation collection efficiency of a solar cell subsequently fabricated there from. The textured surface may have a randomized pattern, such as a surface obtained from basic pH etching of a single crystalline substrate. In an embodiment, texturizing the light-receiving surface 206 of the substrate 200 includes treating the light-receiving surface 206 with an aqueous alkaline process 222. In one such embodiment, the aqueous alkaline process 22 includes performing wet etching of the light-receiving surface 206 using an aqueous potassium hydroxide (KOH) solution of approximately 2 weight percent, at a temperature approximately in the range of 50-85 degrees Celsius, for a duration approximately in the range of 10-20 minutes. In an embodiment, the operation described in association with FIG. 2B is not performed, and texturizing the light-receiving surface 206 of the substrate 200 is performed immediately following treating the light-receiving surface 206 of the substrate 200 with the gaseous ozone process 210. In an embodiment, the texturization is followed by a rinse, e.g., with deionized (DI) water.

In an embodiment, referring to FIG. 2D, subsequent to texturizing the light-receiving surface 206/220 of the substrate 200, a back-contact solar cell 290 is fabricated from the substrate 200. The back-contact solar cell 290 may include metal contacts 250 formed on a patterned dielectric layer 240 on the back surface 204 of the substrate 200, as depicted in FIG. 2D. In one embodiment, an anti-reflective coating layer 254 is formed on and conformal with light-receiving surface 206/220 of substrate 200. In one embodiment, the plurality of metal contacts 250 is formed by depositing and patterning a metal-containing material within patterned dielectric layer 240 and on the plurality of active regions 202. In a specific such embodiment, the metal-containing material used to form the plurality of metal contacts 250 is composed of a metal such as, but not limited to, aluminum, silver, palladium or alloys thereof. In accordance with an embodiment of the present invention, a back side contact solar cell 290 is thus formed.

In another embodiment, referring to FIG. 2E, subsequent to texturizing a light-receiving surface of a substrate, a back-contact solar cell 299 is fabricated. In contrast to the structure of FIG. 2D, the solar cell 299 has active regions formed above a substrate. Specifically, the solar cell 299 includes alternating P+ (262) and N+ (260) active regions formed, e.g., in polycrystalline silicon on a thin dielectric layer 270 on substrate 200′. The back-contact solar cell 299 may include metal contacts 278 formed on a patterned dielectric layer 274 on the back surface of the substrate 200′, as depicted in FIG. 2E. In one embodiment, an anti-reflective coating layer 268 is formed on and conformal with a light-receiving surface of substrate 200′. In an embodiment, during texturizing the light-receiving surface as described in association with FIG. 2C, a portion 276 of the back surface of the substrate 200′ is textured, as depicted in FIG. 2E. For example, trenches formed between active regions 260 and 262 may be texturized at the side of the solar cell opposite the light receiving surface.

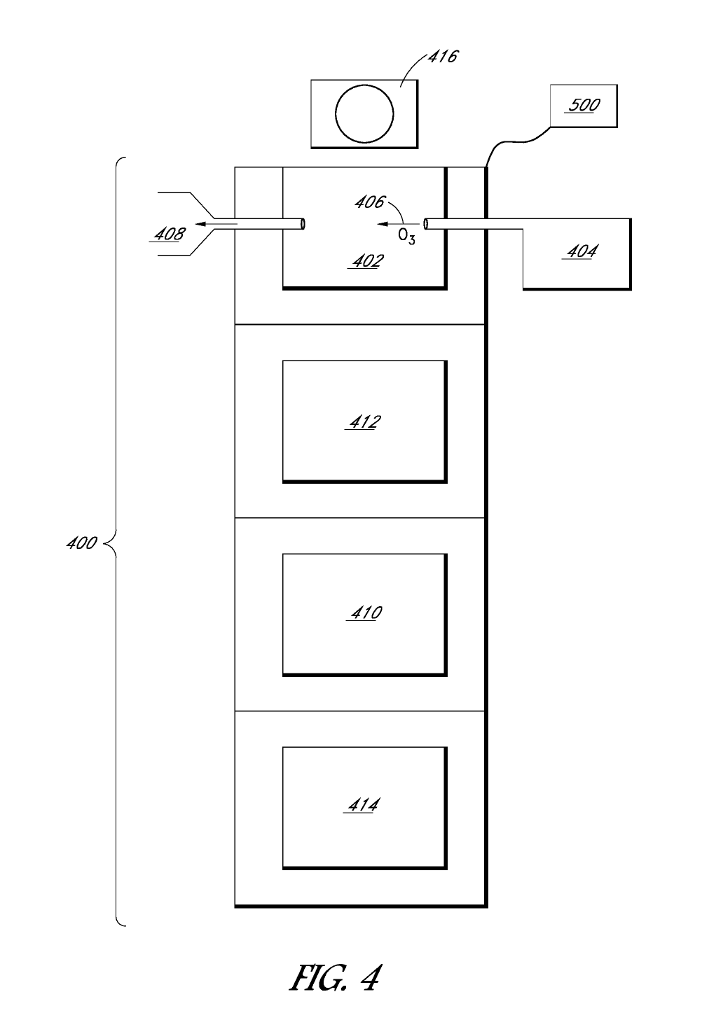

Experiments were performed to illustrate the benefits of using a gaseous ozone treatment prior to texturizing a light-receiving surface of a solar cell. For example, FIG. 3 is a plot 300 showing Jsc (short circuit current) improvement (mA/cm²) as a function of the use or non-use of a gaseous ozone pre-treatment operation, in accordance with an embodiment of the present invention. Improved texturing may decrease the reflectance of the front surface and may result in more photon capture and a higher short circuit current. Referring to FIG. 3, several hundred device wafers were either directly textured (NO ozone pre-treatment before texturing), or exposed to ozone gas for 60 seconds prior to texturing (Yes ozone pre-treatment before texturing). Plot 300 demonstrates the improvement of short circuit current associated with the improved texturing. Specifically, in an embodiment, the Jsc improvement is due to improved texturing and passivation on a surface free from organic residue. In a specific embodiment, a short circuit improvement of approximately 0.1 mA/cm² is achieved with a process having an improved texturing based on an ozone gas pre-treatment.

In an embodiment, as described above, ozone gas is used to oxidize a silicon wafer prior to performing an alkaline texturing process. The ozone gas may be used to breakdown organic residue on silicon wafers, eliminating micro-masks that otherwise may lead to uneven and poor quality texturing. A source of ozone gas may be retrofitted onto a wafer loading area of existing texturing equipment to improve texturing with minimal additional cost. Ozone is an environmentally friendly alternative to many chemical processes. It has a high reduction/oxidation (redox) potential and may be generated at the point of use and readily converted back to oxygen after use.

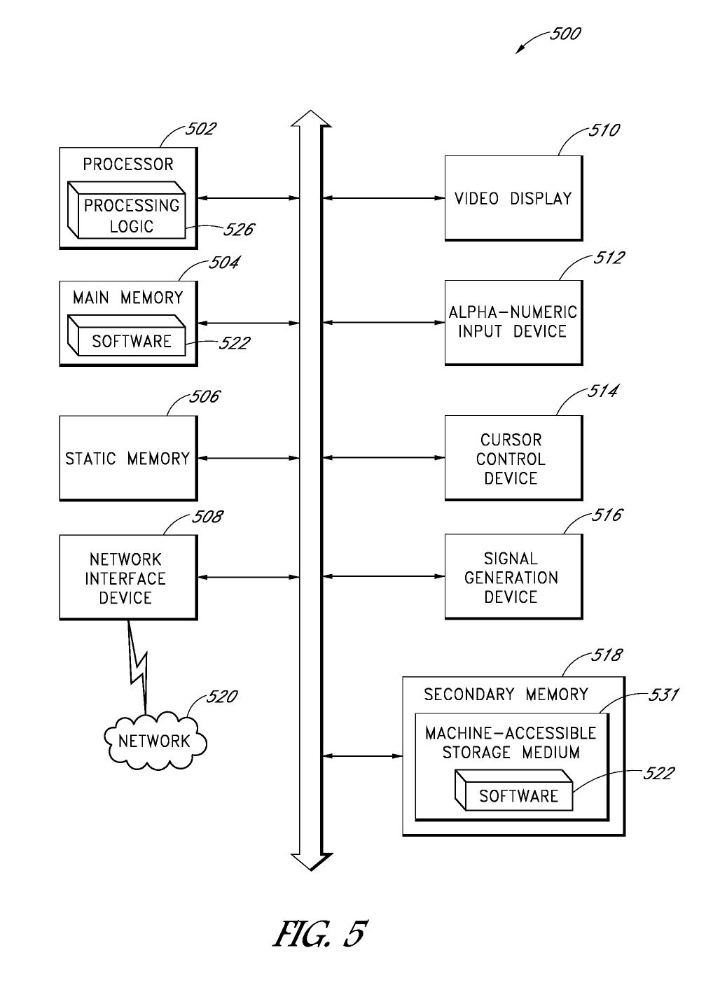

As an exemplary illustration, FIG. 4 is a block diagram of an apparatus for fabricating solar cells, in accordance with an embodiment of the present invention. Referring to FIG. 4, an apparatus 400 for forming a solar cell includes a first chamber 402 configured for coupling a gaseous ozone (O₃) source 404 and for flowing a stream of ozone gas 406 across a substrate in the first chamber 402. The chamber 402 may further be configured to have unused portions of the ozone stream collected at a collection region 408. A second chamber 410 is included and configured for treating a substrate with an aqueous alkaline texturizing process.

In an embodiment, the apparatus 400 further includes a third chamber 412 disposed between the first 402 and second chambers 410 and configured for treating a substrate with a pre-texturing aqueous alkaline process prior to treating with the aqueous alkaline texturizing process of the second chamber 410. A drying station 414 may also be included, as depicted in FIG. 4. Also, apparatus 400 may be configured to dock with a wafer carrier 416. In an embodiment, although not depicted, a rinse station or tank is associated with one of, or both of, third chamber 412 and second chamber 410. The rinse station or tank may be used to perform a rinse with deionized (DI) water.

In an embodiment, chamber 402 is a load/unload or load/lock chamber such as included with a wet bench tool from Rena, GmbH of Gütenbach, Black Forest, Germany. In one such embodiment, ozone is flowed into the chamber and purges the chamber of atmospheric conditions. In a specific embodiment, the chamber 402 is evacuated prior to flowing ozone therein to purge, or evac and refill. In an embodiment, chamber 410 for texturing is a wet cleans chamber such as, but not limited to, a single wafer chamber, a single side spray chamber or tank, or a batch tank. In an embodiment, ozone generator 404 is configured to generate ozone from a corona discharge with oxygen (O₂) gas as a source. In a specific embodiment, the ozone generator 404 is configured to provide an amount of ozone to chamber 402 below approximately 5 standard liter per minute (slm). Examples of suitable ozone generators include, but are not limited to SEMOZON® AX8407, a high concentration, ultra-clean ozone generator available from MKS Instruments, Inc. of Andover, Mass., USA. The AX8407 ozone generator converts pure oxygen into ozone through silent electrical discharge. It requires only minute levels of dopant nitrogen gas. As a result, the ozone is ultra-clean and the presence of contaminants, e.g. NOx compounds, is extremely low.

In an aspect of the present invention, embodiments of the inventions are provided as a computer program product, or software product, that includes a machine-readable medium having stored thereon instructions, which is used to program a computer system (or other electronic devices) to perform a process or method according to embodiments of the present invention. A machine-readable medium may include any mechanism for storing or transmitting information in a form readable by a machine (e.g., a computer). For example, in an embodiment, a machine-readable (e.g., computer-readable) medium includes a machine (e.g., a computer) readable storage medium (e.g., read only memory (“ROM”), random access memory (“RAM”), magnetic disk storage media or optical storage media, flash memory devices, etc.).

FIG. 5 illustrates a diagrammatic representation of a machine in the form of a computer system 500 within which a set of instructions, for causing the machine to perform any one or more of the methodologies discussed herein, is executed. For example, in accordance with an embodiment of the present invention, FIG. 5 illustrates a block diagram of an example of a computer system configured for performing a method of fabricating a solar cell. In alternative embodiments, the machine is connected (e.g., networked) to other machines in a Local Area Network (LAN), an intranet, an extranet, or the Internet. In an embodiment, the machine operates in the capacity of a server or a client machine in a client-server network environment, or as a peer machine in a peer-to-peer (or distributed) network environment. In an embodiment, the machine is a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers or processors) that individually or jointly execute a set (or multiple sets) of instructions to perform any one or more of the methodologies discussed herein. In one embodiment, the machine-computer system 500 is included with or associated with process tool 400, as depicted in FIG. 4.

The example of a computer system 500 includes a processor 502, a main memory 504 (e.g., read-only memory (ROM), flash memory, dynamic random access memory (DRAM) such as synchronous DRAM (SDRAM), etc.), a static memory 506 (e.g., flash memory, static random access memory (SRAM), etc.), and a secondary memory 518 (e.g., a data storage device), which communicate with each other via a bus 530. In an embodiment, a data processing system is used.

Processor 502 represents one or more general-purpose processing devices such as a microprocessor, central processing unit, or the like. More particularly, in an embodiment, the processor 502 is a complex instruction set computing (CISC) microprocessor, reduced instruction set computing (RISC) microprocessor, very long instruction word (VLIW) microprocessor, processor implementing other instruction sets, or processors implementing a combination of instruction sets. In one embodiment, processor 502 is one or more special-purpose processing devices such as an application specific integrated circuit (ASIC), a field programmable gate array (FPGA), a digital signal processor (DSP), network processor, or the like. Processor 502 executes the processing logic 526 for performing the operations discussed herein.

In an embodiment, the computer system 500 further includes a network interface device 508. In one embodiment, the computer system 500 also includes a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

In an embodiment, the secondary memory 518 includes a machine-accessible storage medium (or more specifically a computer-readable storage medium) 531 on which is stored one or more sets of instructions (e.g., software 522) embodying any one or more of the methodologies or functions described herein, such as a method for managing variability of output from a photovoltaic system. In an embodiment, the software 522 resides, completely or at least partially, within the main memory 504 or within the processor 502 during execution thereof by the computer system 500, the main memory 504 and the processor 502 also constituting machine-readable storage media. In one embodiment, the software 522 is further transmitted or received over a network 520 via the network interface device 508.

While the machine-accessible storage medium 531 is shown in an embodiment to be a single medium, the term “machine-readable storage medium” should be taken to include a single medium or multiple media (e.g., a centralized or distributed database, or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of embodiments of the present invention. The term “machine-readable storage medium” shall accordingly be taken to include, but not be limited to, solid-state memories, and optical and magnetic media.

Thus, methods of fabricating solar cells and apparatuses for fabricating solar cells have been disclosed. In accordance with an embodiment of the present invention, a method of fabricating a solar cell includes treating a light-receiving surface of a substrate with a gaseous ozone (O₃) process. Subsequently, the light-receiving surface of the substrate is texturized. In one such embodiment, the gaseous ozone process includes flowing a stream of ozone gas across the light-receiving surface of the solar cell. In accordance with an embodiment of the present invention, an apparatus for forming a solar cell includes a first chamber configured for coupling a gaseous ozone (O₃) source and for flowing a stream of ozone gas across a substrate in the first chamber. A second chamber is configured for treating a substrate with an aqueous alkaline texturizing process. In one such embodiment, a third chamber is disposed between the first and second chambers and configured for treating a substrate with a second aqueous alkaline process prior to treating with the aqueous alkaline texturizing process of the second chamber.

What is claimed is:

1. A method of fabricating a solar cell, the method comprising:
treating a light-receiving surface of a substrate with a gaseous ozone (O₃) process; and, subsequently,
texturizing the light-receiving surface of the substrate.

2. The method of claim 1, wherein the gaseous ozone process comprises flowing a stream of ozone gas across the light-receiving surface of the substrate.

3. The method of claim 2, wherein flowing the stream of ozone gas comprises maintaining the substrate at a temperature approximately in the range of 15-40 degrees Celsius and flowing for a duration approximately in the range of 1-3 minutes.

4. The method of claim 1, wherein treating the light-receiving surface of the substrate with the gaseous ozone process comprises removing at least a portion of an organic residue disposed on the light-receiving surface of the substrate.

5. The method of claim 4, wherein removing the portion of the organic residue comprises oxidizing the organic residue according to the equation:
O₃ (g)+organic residue (s)→O₂ (g)+oxidized organic species (g).

6. The method of claim 1, wherein texturizing the light-receiving surface of the substrate comprises treating the light-receiving surface with an aqueous alkaline process.

7. The method of claim 6, wherein the aqueous alkaline process comprises wet etching the light-receiving surface using an aqueous potassium hydroxide (KOH) solution of approximately 2 weight percent, at a temperature approximately in the range of 50-85 degrees Celsius, for a duration approximately in the range of 10-20 minutes.

8. The method of claim 7, further comprising:
subsequent to treating the light-receiving surface of the substrate with the gaseous ozone process and prior to texturizing the light-receiving surface of the substrate, treating the light-receiving surface using an aqueous potassium hydroxide (KOH) solution having a weight percent approximately in the range of 20-45, at a temperature approximately in the range of 60-85 degrees Celsius, for a duration approximately in the range of 60-120 seconds.

9. The method of claim 7, wherein texturizing the light-receiving surface of the substrate is performed immediately following treating the light-receiving surface of the substrate with the gaseous ozone process.

10. The method of claim 1, further comprising:
subsequent to texturizing the light-receiving surface of the substrate, forming a back-contact solar cell from the substrate, wherein texturizing the light-receiving surface of the substrate further comprises texturizing at least a portion of a surface of the substrate opposite the light-receiving surface.

11. A solar cell fabricated according to the method of claim 1.

12. A method of fabricating a solar cell, the method comprising:
treating a light-receiving surface of a substrate with a gaseous ozone (O₃) process; and, subsequently,
treating the light-receiving surface using an aqueous potassium hydroxide (KOH) solution having a weight percent approximately in the range of 20-45, at a temperature approximately in the range of 60-85 degrees Celsius, for a duration approximately in the range of 60-120 seconds; and, subsequently,
texturizing the light-receiving surface of the substrate and at least a portion of a surface of the substrate opposite the light-receiving surface, the texturizing comprising treating the substrate with an aqueous alkaline process; and, subsequently,
forming a back-contact solar cell from the substrate by forming contacts on the surface of the substrate opposite the light-receiving surface.

13. The method of claim 12, wherein the gaseous ozone process comprises flowing a stream of ozone gas across the light-receiving surface of the substrate.

14. The method of claim 13, wherein flowing the stream of ozone gas comprises maintaining the substrate at a temperature approximately in the range of 15-40 degrees Celsius and flowing for a duration approximately in the range of 1-3 minutes.

15. The method of claim 12, wherein treating the light-receiving surface of the substrate with the gaseous ozone process comprises removing at least a portion of an organic residue disposed on the light-receiving surface of the substrate.

16. The method of claim 15, wherein removing the portion of the organic residue comprises oxidizing the organic residue according to the equation:
O₃ (g)+organic residue (s)→O₂ (g)+oxidized organic species (g).

17. The method of claim 12, wherein the aqueous alkaline process comprises wet etching the substrate using an aqueous potassium hydroxide (KOH) solution of approximately 2 weight percent, at a temperature approximately in the range of 50-85 degrees Celsius, for a duration approximately in the range of 10-20 minutes.

18. A solar cell fabricated according to the method of claim 12.

19. An apparatus for forming a solar cell, the apparatus comprising:
a first chamber configured for coupling a gaseous ozone (O₃) source and for flowing a stream of ozone gas across a substrate in the first chamber; and
a second chamber configured for treating a substrate with an aqueous alkaline texturizing process.

20. The apparatus of claim 19, further comprising:
a third chamber disposed between the first and second chambers and configured for treating a substrate with a second aqueous alkaline process prior to treating with the aqueous alkaline texturizing process of the second chamber.
